(19) United States
(12) Patent Application Publication
(10) Pub. No.: US 2006/0043989 A1
(43) Pub. Date: Mar. 2, 2006

(54) Film-type testing jig and testing method

(76) Inventor: Ying-Ho Ko, Taipei (TW)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/928,427

(22) Filed: Aug. 30, 2004

(51) Int. Cl. G01R 31/02

(52) U.S. Cl. 324/755

(57) ABSTRACT

A film type testing jig and a testing method are suitable for an electronic element to be tested having electrical contacts. At least one movable member whose surface is provided with a testing film is prepared. After the electronic element to be tested is fixed in position, conductive circuits on the testing film come into contact with the electrical contacts of the electronic element by movement of the movable member. By such arrangement, testing equipment that is electrically connected to the testing film can be used to determine a testing result of the electronic element, and the above film-type testing jig and testing method provide advantages such as protection of the electronic element, automatic and fast test performance, and a long lifetime of the jig.

### FIELD OF THE INVENTION

The present invention relates to testing jigs and testing methods, and more particularly, to a film-type testing jig and a film-type testing method for testing electrical properties of electronic elements such as memory modules.

### BACKGROUND OF THE INVENTION

For memory modules or other electronic elements that are massively applied in Semiconductor products, a number of tests are carried out during fabrication to determine yields and electrical properties of the memory modules or electronic elements and to collect and then discard defective products such that performance and efficiency of the fabricated products can be assured. For example, a memory chip test during chip fabrication, a package reliability test after a packaging process, and a card-type memory module test after modularization are all critical tests performed prior to completing the product fabrication.

As to the testing technique for memory module, a memory module to be tested is usually mounted and electrically connected to a testing jig, allowing signals from the memory module to be transmitted via the testing jig to a testing board such as printed circuit board. Then electrical properties of the memory module can be determined through the use of electrical conduction between the testing board and the memory module. The testing board is further externally connected to a recognition device that can display a status of the electrical conduction between the testing board and the memory module, such that a user is able to recognize a testing result of the memory module.

A conventional testing jig is electrically connected via automatic probes to the memory module to be tested. Referring to FIG. 4, two rows of probes 40 come into contact with a plurality of golden fingers 42 located at a side of a card-type memory module 41 to perform a yield test for testing electrical properties of circuitry between the golden fingers 42 and a memory chip. However, this probe testing method has a limitation that the probes 40 occupy certain space, and a pitch between the adjacent probes 40 is difficult to be reduced, which is thus not suitable for the memory module 41 with golden fingers 42 having a rather small pitch. As the memory module becomes having more complicated circuitry, electrical, contacts or fingers formed on a surface of the memory module are also arranged in a higher density, malting the pitch between the adjacent electrical contacts or fingers further reduced such that the probe testing method is no longer feasible. Moreover, the use of the probes 40 may cause significant drawbacks such as damage to surfaces of the fingers 42 (e.g. scratches), signal distortion, and difficulty in controlling testing contact pressures. Furthermore, such a testing jig inherently has some disadvantages such as accuracy or lubrication between the assembled elements, or deformation of the probes after the test, thereby making it difficult to control the fabrication quality, reduce the fabrication cost, and perform maintenance and replacement of the jig. Therefore, a new testing method should be developed.

Accordingly, other testing jigs have been proposed in the industry. Referring to FIG. 5A showing a plug-type testing method, a testing board 50 such as motherboard is provided, and a socket 51 is electrically connected to the testing board 50. The socket 51 is formed with a slot 56 in which two rows of electrical contacts 52 are arranged. A memory module 53 to be tested can have fingers 54 on a side thereof being inserted into the slot 56 and then be fixed to the socket 51 by fastening latches 55 located at two ends of the slot 56 as shown in FIG. 5B. Thus each of the electrical contacts 52 is in contact with and electrically connected to one of the fingers 54 on the memory module 53 to carry out an electrical property test on the fingers 54 and the memory chip. The related prior arts include for example U.S. Pat. No. 6,357,022, Taiwanese Patent No. 492619, Taiwanese Patent No. 561263. and Taiwanese Patent No. 564945.

The plug-type testing method is capable of altering a design of the socket 51 and a density of the electrical contacts 52 according to a size and circuit layout of the memory module 53, and accurately positioning the memory module 53, thereby effectively eliminating the drawbacks caused by the probe-type testing method such as signal distortion etc. However, the plug-type testing method may have a primary drawback that lifetimes of the socket 51 and slot 56 are relatively short. After several hundred tests have been carried out, the electrical contacts 52 in the slot 56 may be damaged and need to be replaced. Moreover, during insertion or withdrawal of the memory module 53 in or from the slot 56, the fingers 54 of the memory module 53 may be scraped and damaged. Furthermore, this plug-type testing method requires gentle manual inserting/withdrawing manipulation and thus accurate automation cannot be performed, such that the testing speed is hard to be improved and the testing contact pressures cannot be uniformly controlled, malting the plug-type testing method not able to meet the requirement of mass production.

Therefore, the problem to be solved here is to provide a new testing jig and a new testing method in which the jig is connected to testing equipment comprising a printed circuit board and a conventional recognition device to accelerate the testing performance, while not damaging electronic elements to be tested during a test as well as providing advantages such as easy maintenance, a long lifetime and uniform contact pressures.

### SUMMARY OF THE INVENTION

In light of the above prior-art drawbacks, an objective of the present invention is to provide a film-type testing jig and a film-type testing method, by which an electronic element to be tested would not be damaged during a test.

Another objective of the present invention is to provide a film-type testing jig and a film-type testing method to perform an automatic and fast test.

Still another objective of the present invention is to provide a film-type testing jig and a film-type testing method, by which easy maintenance and replacement can be achieved.

A further objective of the present invention is to provide a film-type testing jig and a film-type testing method, by which contact pressures during a test can be uniformly controlled.

A further objective of the present invention is to provide a film-type testing jig and a film-type testing method, by which a relatively long lifetime of the jig is provided.

In accordance with the above and other objectives, the present invention proposes a film-type testing jig for electrically connecting an electronic element to be tested having electrical contacts to a testing board. The testing jig comprises a base having at least one positioning portion for fixing the electronic element to be tested in position; at least one movable member whose surface is provided with a testing film having conductive circuits, to allow the conductive circuits of the testing film to come into contact with the electrical contacts of the electronic element via movement of the movable member, and allow the conductive circuits to be electrically connected to the testing board; and at least one driving unit for actuating the movable member.

A film-type testing method proposed in the present invention comprises the steps of: providing an electronic element to be tested having electrical contacts; providing at least one movable member whose surface is provided with a testing film having conductive circuits, wherein the conductive circuits of the testing film are electrically connected to a testing board; fixing the electronic element to be tested in position, to allow the conductive circuits of the testing film come into contact with the electrical contacts of the electronic element via movement of the movable member; and determining a testing result of the electronic element via the testing board.

The foregoing testing film is made of a high molecular polymer material. The conductive circuits comprise copper conductive bumps and conductive traces both fabricated by a semiconductor lithography technique. Furthermore, the conductive traces are each connected to one of the conductive bumps and are arranged in parallel on a surface of the testing film to be further electrically connected to a testing circuit on the testing board and an external recognition device.

Therefore, when a test is carried out on the electronic element, an electrical connection relationship of “electrical contacts to film-type conductive bumps to film-type conductive traces to testing circuit of the testing board” is established via the contact between the electrical contacts (such as fingers) of the electronic element and the testing film, so as to allow the test to be completed is completed and to determine any short circuit, circuit break and performance status of the electronic element. The present invention also provides advantages such as protection of the fingers, automatic test performance, and easy maintenance and a long lifetime of the testing jig, which can eliminate drawbacks caused by the conventional testing methods.

### BRIEF DESCRIPTION OF THE DRAWINGS

The present invention can be more fully understood by reading the following detailed description of the preferred embodiments, with reference made to the accompanying drawings, wherein:

FIG. 1A is a schematic diagram showing a testing jig not mounted with a testing film according to the present invention;

FIG. 1B is a schematic diagram showing the testing jig during a process of mounting the testing film according to the present invention;

FIG. 1C is a schematic diagram showing the testing jig mounted with the testing film according to the present invention;

FIG 2 is a schematic diagram showing the testing film according to the present invention;

FIGS. 3A and 3B are schematic diagrams showing the testing jig during a test according to the present invention;

FIG. 3C is a side view showing the testing jig during the test according to the present invention;

FIG. 4 (PRIOR ART) is a schematic diagram showing a conventional probe-type testing jig; and

FIGS. 5A and 5B (PRIOR ART) are schematic diagrams showing a conventional plug-type testing jig during a test.

### DETAILED DESCRIPTION OF THE PREFERRED EMBODIMENTS

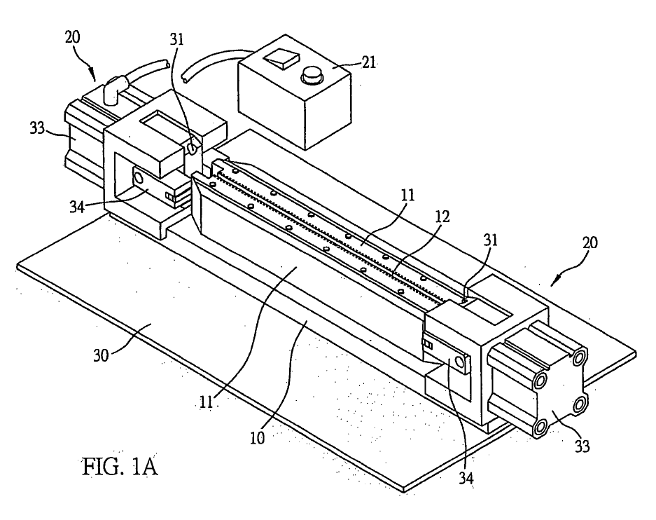

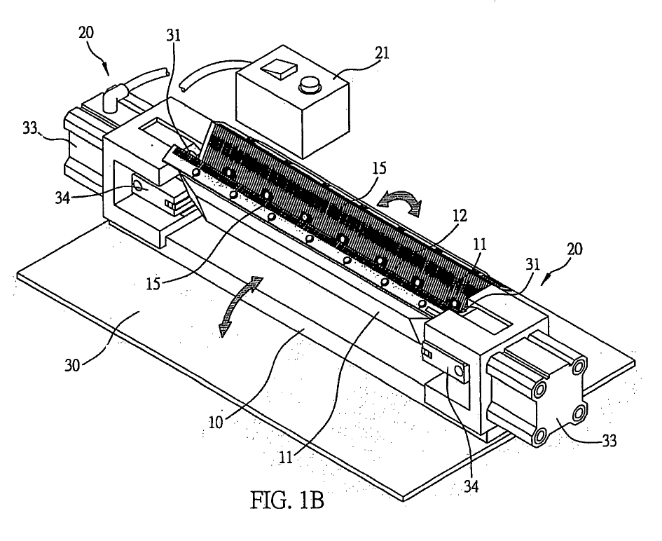

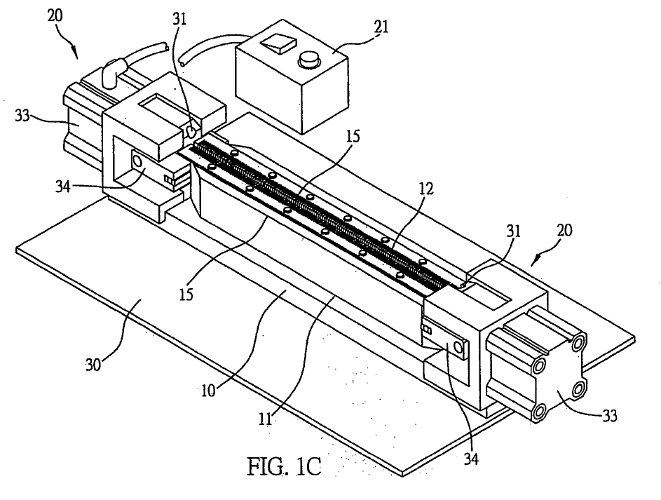

The preferred embodiments of a film-type testing jig and a film-type testing method proposed in the present invention are described in detail below with reference to FIGS. 1 to 3. In the present invention, a memory module is taken here as an example of an electronic element to be tested. However, it should be understood that other electronic elements to be tested having electrical contacts are also suitable for the testing jig and the testing method proposed in the present invention. Furthermore, the testing jig in the present invention is externally connected to conventional testing equipment comprising a testing board and a recognition device. The conventional testing equipment is not to be further described hereinafter.

Referring to FIGS. 1A and 1B, the film-type testing jig proposed in the present invention comprises a base 10 and two driving units 20 located respectively at two opposite ends of the base 10. Two positioning portions 31 such as positioning grooves are respectively located close to the driving units 20 at the two ends of the base 10. The driving units 20 are externally connected to a driving switch 21 having a solenoid valve. The base 10 further comprises two movable members 11 such as clamping members able to oscillate, which are located between the two positioning portions 31 and pivoted on the driving unit 20, such that the movable members 11 can be actuated by the driving unit 20 to oscillate to form a groove-shaped gap 12. Moreover, a printed circuit board 30 serving as a testing board is mounted under the base 10 of the testing jig. The printed circuit board 30 is provided thereon with a testing circuit externally connected to a recognition device (not shown) to carry out a test for the memory module and recognize a testing result. The printed circuit board 30 and the recognition device are common external testing equipment of the conventional testing jig and therefore are not to be further described.

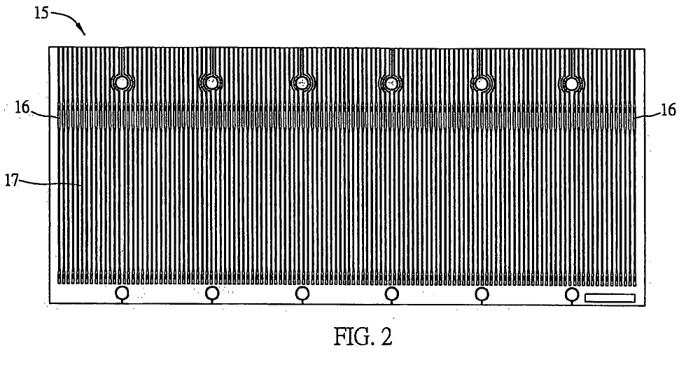

Referring to FIG 1B, a characteristic feature of the present invention is to attach a testing film 15 to each of the two movable members 11 and cover a surface of each of the movable members 11. The testing film 15 is made of a high molecular polymer material. As shown in FIG. 2, the testing film 15 is formed on its surface with a row of conductive circuits, each of which comprises a conductive bump 16 and a conductive trace 17. The conductive traces 17 are arranged in parallel and spaced apart from each other by a predetermined pitch. The conductive bump 16 and the conductive trace 17 are made of copper materials having Ni alloy plated on surfaces thereof. Referring to FIG 1C, when the two movable members 11 are actuated to oscillate to form the groove-shaped gap 12, each of the testing films 15 is partially located on an inner wall of the groove-shaped gap 12, and the conductive bumps 16 and conductive traces 17 are protruded in the groove-shaped gap 12. By electrically connecting the conductive traces 17 to the printed circuit board 30 underneath the base 10, the testing films 15 can be electrically coupled to the testing circuit of the printed circuit board 30.

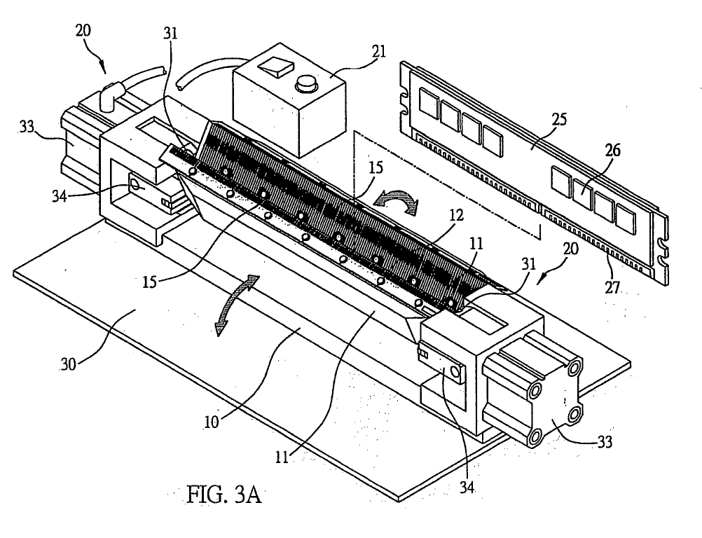

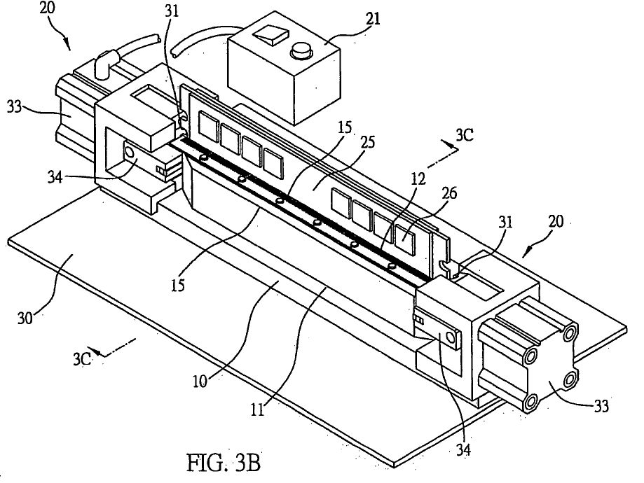

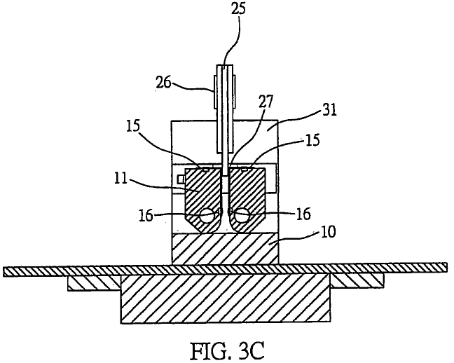

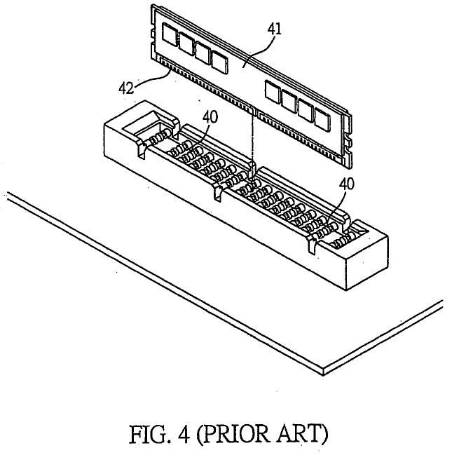

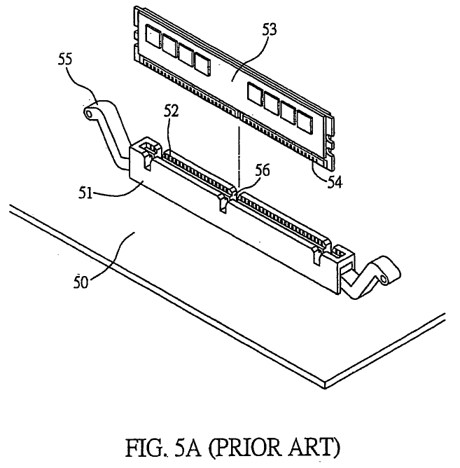

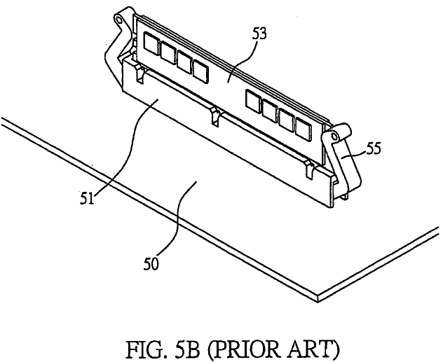

Referring to FIGS. 3A and 3B, when an electrical property test for memory module is carried out, a memory module 25 to be tested is placed into the two positioning portions or grooves 31 at the two ends of the base 10 and is also received between the two movable members 11 that are located between the two positioning portions 31. The memory module 25 in this embodiment can be for example, a double data rate dynamic random access memory (DDR DRAM), which is a card-type module having a plurality of memory chips 26. One side of the memory module 25 is provided with a TOW of electrical contacts such as golden fingers 27 electrically connected to the memory chips 26. When the side of the memory module 25 having the golden fingers 27 is inserted between the two movable members 11, the external driving switch 21 can be turned on and the two driving units 20 can actuate the two movable members 11 to oscillate, so as to allow the movable members 11 to form the groove-shaped gap 12 in which the memory module 25 is received and clamped by the movable members 11 in a manner that the plurality of conductive bumps 16 on the testing films 15 respectively come into contact with the golden fingers 27 of the memory module 25 as shown in FIG. 3C. As a result, the conductive traces 17 on the testing film 15 are electrically connected to the memory module 25, and thus the electrical property test can be performed and completed on the memory module 25 by electrically connecting the conductive traces 17 to the testing circuit on the printed circuit board 30 and the external recognition device (not shown), such that yields of the memory module 25 and the golden fingers 27 can be determined by the printed circuit board 30 and the recognition device.

The driving unit 20 in this embodiment can comprise a drive source 33 and an operating mechanism 34. Referring to the drawings, the operating mechanism 34 is a rocking arm mechanism and the drive source 33 is a pneumatic cylinder. When the driving switch 21 is turned on, the pneumatic cylinder 33 is able to actuate oscillation of the rocking arm mechanism 34, so as to oscillate the two movable members 11 pivoted on the driving units 20 to clamp the memory module 25 therebetween. The drive source 33 can be replaced by other drive sources such as an oil cylinder, and the rocking arm mechanism 34 can be replaced by other mechanisms having an equivalent effect.

The foregoing positioning portions 31 located at the two ends of the base 10 are described as positioning grooves for receiving and positioning the memory module 25 to be tested. However, the number and the positioning method of the positioning portions 31 are not limited to those depicted in this embodiment. Any positioning portions capable of fixing the memory module 25 to be tested in position on the base 10 to be clamped by the movable members 11 are suitable. Also, the number of the movable members 11 can be altered according to the memory module 25 to be tested depending on the practical requirement. For example, if the golden fingers 27 of the memory module 25 are all located on the same side, when the memory module 25 is fixed in position, only one movable member 11 is sufficient to be oscillated to allow the conductive bump 16 on the testing film 15 to contact the golden fingers 27.

In comparison to the conventional probe- or plug-type testing jigs, the film-type testing jig in the present invention is capable of preventing damage to the golden fingers 27 of the memory module 25 and allowing the test to be automatically and fast performed. Moreover, the conductive circuits on the testing film 15 can be fabricated simply by a conventional semiconductor lithography technique known in combination with a yellow light process, such that the testing cost and fabrication difficulty are effectively reduced. Furthermore, the testing method in the present invention allows long-term usage without damaging the jig, and only scheduled replacement of the low-cost testing films 15 is required. Thus, the testing jig in the present invention has advantages of easy maintenance and a long lifetime. In addition, since the movable members 11 in the present invention are actuated by control methods using the pneumatic cylinder, the oil cylinder and the rocking arm mechanism 34, uniform contact pressures can be maintained between the movable members 11 and the memory module 25 by controlling the two driving units 20, such that the testing quality would not be degraded due to incomplete contact. AU the above advantages and effects cannot be achieved by the conventional testing methods.

The film-type testing method using the film-type testing jig in the present invention comprises the following steps. First, a memory module 25 to be tested having a plurality of golden fingers 27 is prepared, and at least one movable member 11 whose surface is mounted with a testing film 15 having conductive bumps 16 and conductive traces 17 is provided, wherein the conductive traces 17 of the testing film 15 are electrically connected to a printed circuit board 30. Then, the memory module 25 to be tested is positioned, and the conductive bumps 16 of the testing film 15 are allowed to be in contact with the corresponding golden fingers 27 of the memory module 25 by movement of the movable member 11. Finally, the test is performed on the memory module 25 through the electrical connection between the printed circuit board 30, the testing film 15 and the memory module 25, and a testing result of the memory module 25 can be recognized by the printed circuit board 30 and a recognition device externally connected to the printed circuit board 30, so as to determine the electrical yield of each of the golden fingers 27 of the memory module 25 and identify any short circuit, circuit break and performance status of the memory module 25.

Therefore, according to the foregoing embodiment, the film-type testing jig and the testing method proposed in the present invention employ the design of the testing film, conductive bumps and conductive traces, without using the conventional probe- or plug-type contact, to protect fingers of an electronic element to be tested and also achieve significant advantages such fast test performance, easy maintenance and a long lifetime of the jig, and uniform testing contact pressures.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A film-type testing jig for electrically connecting an electronic element to be tested having electrical contacts to a testing board, the testing jig comprising:
a base having at least one positioning portion for fixing the electronic element to be tested in position;
at least one movable member mounted on a surface thereof with a testing film having conductive circuits, allowing the conductive circuits of the testing film to be in contact with the electrical contacts of the electronic element via movement of the movable member, wherein the conductive circuits of the testing film are electrically connected to the testing board; and
at least one driving unit for actuating the movable member.

2. The film-type testing jig of claim 1, wherein the conductive circuits of the testing film comprise a plurality of conductive bumps and a plurality of conductive traces connected to the conductive bumps, allowing the conductive bumps to be in contact with the electrical contacts of the electronic element.

3. The film-type testing jig of claim 1, wherein the testing film is made of a high molecular polymer material, and the conductive circuits are made of a copper material.

4. The film-type testing jig of claim 1, wherein the conductive circuits are fabricated by a semiconductor lithography technique.

5. The film-type testing jig of claim 1, wherein the testing board is mounted under the base.

6. The film-type testing jig of claim 1, wherein the testing board is a printed circuit board having a testing circuit, and the testing circuit is externally connected to a recognition device capable of recognizing a testing result.

7. The film-type testing jig of claim 6, wherein the testing circuit of the testing board is electrically connected to the conductive circuits of the testing film.

8. The film-type testing jig of claim 1, wherein the electronic element is a memory module, and the electrical contacts of the electronic element are fingers.

9. The film-type testing jig of claim 1, wherein the at least one positioning portion comprises two positioning grooves located at two opposite ends of the base, allowing the electronic element to be placed and fixed in the two positioning grooves.

10. The film-type testing jig of claim 9, wherein the at least one movable member comprises two clamping members able to oscillate that are located between the two positioning grooves, allowing the electronic element fixed in the two positioning grooves to be clamped by the two clamping members.

11. The film-type testing jig of claim 1, wherein the movable member is mounted on the base.

12. The film-type testing jig of claim 1, wherein the driving unit comprises a drive source and an operating mechanism to actuate the movable member, and wherein the operating mechanism is a rocking arm mechanism, and the drive source is one selected from the group consisting of pneumatic cylinder and oil cylinder.

13. A film-type testing method comprising the steps of:
providing an electronic element to be tested having electrical contacts;
providing at least one movable member mounted on a surface thereof with a testing film having conductive circuits, wherein the conductive circuits of the testing film are electrically connected to a testing board;
fixing the electronic element to be tested in position, so as to allow the conductive circuits of the testing film to come into contact with the electrical contacts of the electronic element via movement of the movable member; and
determining a testing result of the electronic element via the testing board.

14. The film-type testing method of claim 13, wherein the conductive circuits of the testing film comprise a plurality of conductive bumps and a plurality of conductive traces connected to the conductive bumps, allowing the conductive bumps to be in contact with the electrical contacts of the electronic element.

15. The film-type testing method of claim 13, wherein the testing film is made of a high molecular polymer material, and the conductive circuits are made of a copper material.

16. The film-type testing method of claim 13, wherein the conductive circuits are fabricated by a semiconductor lithography technique.

17. The film-type testing method of claim 13, wherein the testing board is a printed circuit board, having a testing circuit, and the testing circuit is externally connected to a recognition device capable of recognizing the testing result.

18. The film-type testing method of claim 17, wherein the testing circuit of the testing board is electrically connected to the conductive circuits of the testing film.

19. The film-type testing method of claim 13, wherein the electronic element is a memory module, and the electrical contacts of the electronic element are fingers.

20. The film-type testing method of claim 13, wherein the movable member is a clamping member able to oscillate.
